(19) United States
(12) Patent Application Publication
(10) Pub. No.: US 2024/0363581 A1
(43) Pub. Date: Oct. 31, 2024

(54) WIRE BONDING APPARATUS AND SEMICONDUCTOR PACKAGE MANUFACTURED USING THE SAME

(71) Applicant: SAMSUNG ELECTRONICS CO., LTD., SUWON-SI (KR)

(72) Inventor: Daewoong Heo, Suwon-si (KR)

(21) Appl. No.: 18/622,131

(22) Filed: Mar. 29, 2024

(30) Foreign Application Priority Data
Apr. 26, 2023 (KR) 10-2023-0054604

(51) Int. Cl. H01L 23/00

(52) U.S. Cl. CPC H01L 24/78; H01L 24/48; H01L 24/745; H01L 2224/48091; H01L 2224/48227; H01L 2224/48465; H01L 2224/745; H01L 2224/78611

(57) ABSTRACT

A capilary of a wire bonding apparatus including: a body having a wire hole formed in an inner central region of the body and through a length of the body, and a wire discharge portion disposed at a lower end portion of the body and including an injection hole in an outer circumference of the wire discharge portion.

### CROSS-REFERENCE TO RELATED APPLICATION

This application claims priority to, and the benefit of Korean Patent Application No. 10-2023-0054604, filed in the Korean Intellectual Property Office on Apr. 26, 2023, the entire contents of which are herein incorporated by reference.

### BACKGROUND

### (a) Technical Field

The present disclosure relates to a wire bonding apparatus and a semiconductor package manufactured using the same.

### (b) Discussion of Related Art

Wire bonding is a technique used in a semiconductor package manufacturing process to connect integrated circuits (ICs) or other semiconductor devices to their packages, or to connect different parts within the devices themselves. Wire bonding may be performed by bonding both ends of a wire to create an electrical connection.

The wire bonding may be performed by attaching a wire supplied through a capillary to an area to be bonded. A force applied to the wire in the process of bonding the wire may cause a crack in the wire. The crack in the wire may be a defect in the semiconductor package affecting device performance or reliability.

### SUMMARY

One aspect of the present disclosure is to provide a wire bonding apparatus that may prevent a crack from occurring by effectively performing bonding using a wire and a semiconductor package manufactured using the same.

However, the present disclosure is not limited to the aspects described herein, and may be extended in various ways within the spirit and scope of the present disclosure.

An embodiment provides a capillary of a wire bonding apparatus, the capillary including: a body having a wire hole formed in an inner central region of the body and through a length of the body, and a wire discharge portion disposed at a lower end portion of the body and comprising an injection hole in an outer circumference of the wire discharge portion.

The wire discharge portion may include a pressing portion disposed at a lower end portion of the wire discharge portion and inclined upward toward an outward direction of the wire discharge portion in at least one region; and a gas injection surface extending upward from the pressing portion, wherein an outer end of the injection hole may be disposed on the gas injection surface.

An inclination of a lower end portion of the gas injection surface may be greater than an inclination of the pressing portion with respect to a direction orthogonal to a vertical direction.

A height from an outer end portion of the pressing portion to the injection hole may be greater than a height of an inner end of the pressing portion.

An inner end portion of the injection hole may be connected to the wire hole.

An inlet flow passage may pass through the body and connect the wire hole to an outer surface of the body.

The inlet flow passage may be inclined downward to the inner end portion.

An inlet-side fastening auxiliary portion may be formed in an area in which an outer end portion of the inlet flow passage is disposed on an outer surface of the body, and the inlet-side fastening auxiliary portion may include a groove structure inwardly recessed or a protrusion structure outwardly protruding.

The wire bonding apparatus may include a spool supplying a wire to the capillary; a driving member movable in a three-dimensional space and including a driving body having a fastening space in which the capillary may be coupled; and a supply passage connected to the fastening space may be formed in the driving body.

A supply-side fastening auxiliary portion may be formed on a surface facing the fastening space and may have a protrusion structure or a groove structure corresponding to the inlet-side fastening auxiliary portion formed in the driving body.

The body may include an inlet flow passage having a first end disposed on an outer surface of the body and a second end connected to an inner end portion of the injection hole.

The inlet flow passage may include an inlet portion including an outer end exposed to an external space through an outer surface of the body; a connection portion connected to an inner end portion of the inlet portion; and a distribution portion connected to the connection portion and an inner end portion of the injection hole.

The distribution portion may be formed in a ring shape.

Another embodiment provides a wire bonding apparatus including: a capillary for discharging a wire; a spool for supplying the wire to the capillary; and a driving member coupled to the capillary and movable in a three-dimensional space, wherein the capillary includes a body having a wire hole formed in an inner central region of the body and through a length of the body, and through which the wire is discharged, and a wire discharge portion disposed at a lower portion of the body, wherein the wire discharge portion includes a pressing portion disposed at a lower end portion of the wire discharge and inclined upward toward an outward direction of the wire discharge in at least one region; and a gas injection surface extending upward from the pressing portion and having an outer circumference at which an outer end of an injection hole for spraying gas is disposed.

A height from an outer end portion of the pressing portion to the injection hole may be greater than a height of an inner end of the pressing portion.

Another embodiment a semiconductor package including: a substrate having a substrate-side junction portion; an electronic device attached to the substrate and having a device-side junction portion; and a connection wire having a first end portion bonded to the substrate-side junction portion and a second end portion bonded to the device-side junction portion, wherein the connection wire has a roughness change region having lower roughness than a region adjacent to at least one of the first end portion and the second end portion.

The roughness change region may be disposed adjacent to a stitch bond region of the connection wire.

The roughness change region may have a lower roughness than a region disposed in an opposite direction based on a cross-section crossing a length direction of the connection wire.

A roughness of a central region of the roughness change region may be lower than that of an outer region thereof.

The roughness change region may be spaced apart from an end of the connection wire by about 28 μm to about 31 μm.

According to embodiments, it may be possible to reduce or prevent cracks from occurring in a process of bonding through wires for manufacturing a semiconductor package.

### BRIEF DESCRIPTION OF THE DRAWINGS

FIG. 1 illustrates a wire bonding apparatus according to an embodiment.

FIG. 2 illustrates a capillary of FIG. 1.

FIG. 3 illustrates a longitudinal cross-sectional view along a length direction of a lower end portion of the capillary of FIG. 1.

FIG. 4 illustrates a transverse cross-sectional view along a direction crossing the length direction of the lower end portion of the capillary of FIG. 1.

FIG. 5 illustrates a longitudinal cross-sectional view along a length direction of a partial section of the capillary of FIG. 1.

FIG. 6 illustrates a driving member of FIG. 1.

FIG. 7 illustrates a longitudinal cross-sectional view taken along line I-I′ of FIG. 6.

FIG. 8 illustrates a state in which primary bonding for manufacturing a semiconductor package is performed through the wire bonding apparatus of FIG. 1.

FIG. 9 illustrates a state in which secondary bonding for manufacturing a semiconductor package is performed through the wire bonding apparatus of FIG. 1.

FIG. 10 illustrates a state when secondary bonding of a wire is performed at a lower end portion of a capillary.

FIG. 11 illustrates one end portion of a connection wire of a semiconductor package after a wire is attached.

FIG. 12 illustrates a roughness change region viewed from a direction crossing a longitudinal direction of a connection wire.

FIG. 13 illustrates a longitudinal cross-sectional view along a length direction of a partial section of a capillary according to an embodiment.

FIG. 14 illustrates a longitudinal cross-sectional view along a length direction of a partial section of a capillary according to an embodiment.

FIG. 15 illustrates a longitudinal cross-sectional view of a driving member according to an embodiment.

FIG. 16 illustrates a longitudinal cross-sectional view along a length direction of a lower end portion of a capillary according to an embodiment.

FIG. 17 illustrates a transverse cross-sectional view along a direction crossing a length direction of a lower end portion of a capillary according to an embodiment.

FIG. 18 illustrates a longitudinal cross-sectional view along a length direction of a partial section of a capillary according to an embodiment.

### DETAILED DESCRIPTION

Aspects of the present disclosure will be described more fully hereinafter with reference to the accompanying drawings, in which embodiments of the disclosure are shown. As those skilled in the art would realize, embodiments may be modified in various different ways, all without departing from the spirit or scope of the present disclosure.

In order to clearly describe aspects of the present disclosure, parts or portions that are irrelevant to the description may be omitted, and identical or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

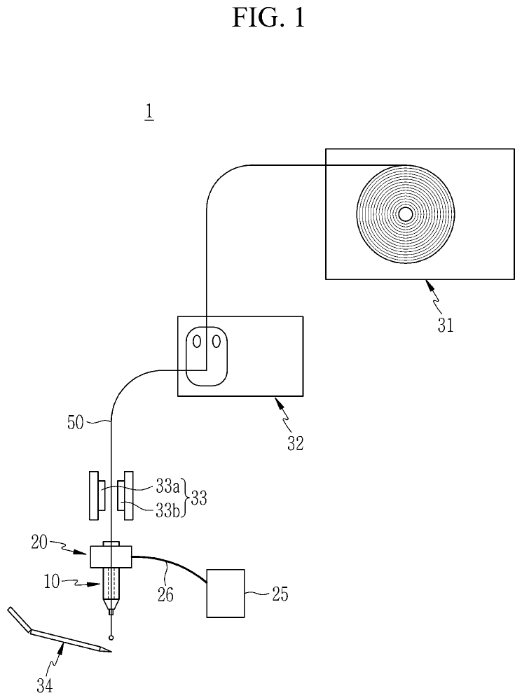

FIG. 1 illustrates a wire bonding apparatus according to an embodiment.

Referring to FIG. 1, a wire bonding apparatus 1 according to an embodiment may include a capillary 10, a driving member 20, a spool 31, and a clamp 33.

The capillary 10 may discharge a wire 50 to an area to be connected to allow the wire 50 to be bonded.

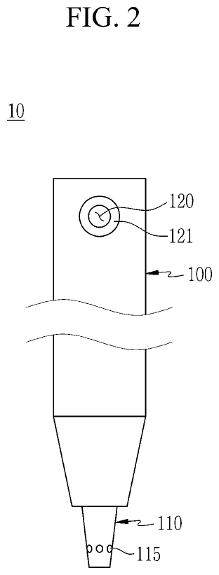

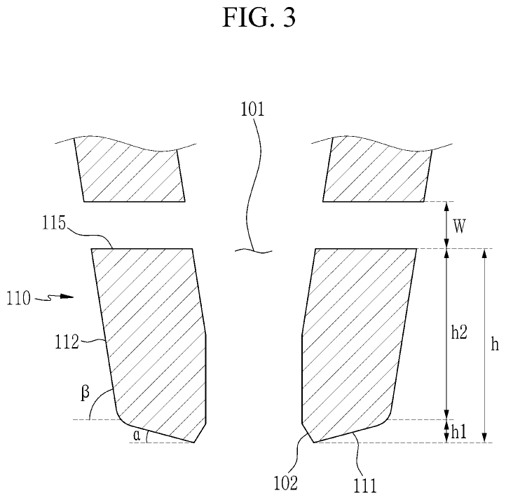

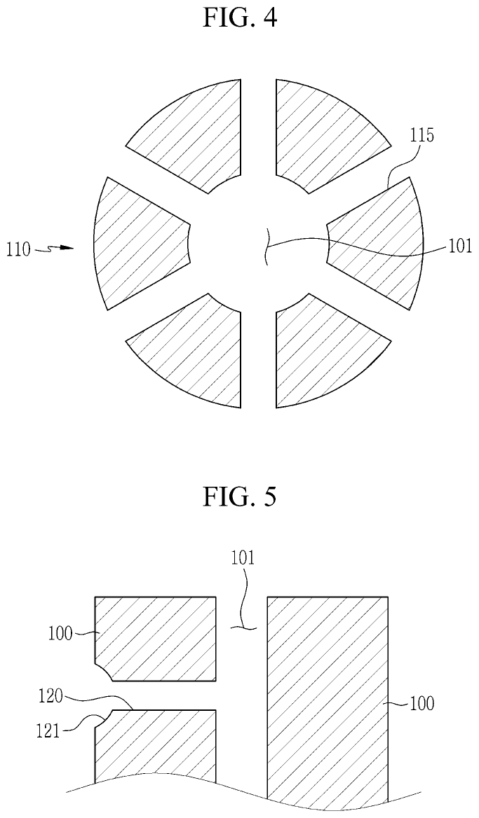

FIG. 2 illustrates a capillary of FIG. 1. FIG. 3 illustrates a longitudinal cross-sectional view along a length direction of a lower end portion of the capillary of FIG. 1. FIG. 4 illustrates a transverse cross-sectional view along a direction crossing the length direction of the lower end portion of the capillary of FIG. 1. FIG. 5 illustrates a longitudinal cross-sectional view along a length direction of a partial section of the capillary of FIG. 1.

Referring to FIG. 2 and FIG. 5, a body 100 of the capillary 10 may have a predetermined length. The body 100 of the capillary 10 may be disposed so that a length direction thereof is directed upward and downward in the view of FIG. 2. A cross-section according to a direction crossing the length direction of the body 100 of the capillary 10 may have a circular, elliptical, or polygonal shape. A wire hole 101 may be formed in an inner central region of the body 100 along the length direction. The wire hole 101 may be formed through the body 100 from an upper end to a lower end of the body 100. The wire hole 101 may be an opening for the wire 50. The wire 50 may move through the wire hole 101, which may be a path for the wire 50 to travel along.

A wire discharge portion 110 may be disposed at the lower end portion of the body 100. The wire discharge portion 110 may discharge the wire 50 downward through the wire hole 101. An area of a cross-section of a direction crossing a length direction of the wire discharge portion 110 may be smaller than the area of the cross-section of the direction crossing the length direction of the upper portion of the body 100. A width of the wire discharge portion 110 may be less than a length of the wire discharge portion 110.

An inner inclined portion 102 may be formed at an inner central region of a lower end portion of the wire discharge portion 110. The inner inclined portion 102 may be inclined toward the outside in the downward direction. Accordingly, the area of the cross-section of the lower end portion of the wire hole 101 crossing the length direction thereof may increase in the downward direction.

An inclination of the inner inclined portion 102 may be the same or different depending on a region. For example, the inner inclined portion 102 may have a straight structure inclined in a vertical direction. In addition, the inner inclined portion 102 may include two or more sections having different inclinations in the vertical direction according to regions. In addition, the inner inclined portion 102 may include a portion that is rounded toward an outer direction in the downward direction in at least some sections.

A pressing portion 111 may be formed in an outer region of a lower end portion of the wire discharge portion 110. The pressing portion 111 may be connected to a lower end of the inner inclined portion 102. The pressing portion 111 may extend from the lower end of the inner inclined portion 102. The pressing portion 111 may meet the lower end of the inner inclined portion 102 at an angled portion. The angled portion may be a vertex or may be rounded. At least one area of the pressing portion 111 may be inclined upward toward an outside of the wire discharge portion 110. For example, the pressing portion 111 may be inclined upward toward an outer direction from an inner end where the pressing portion 111 meets the inner inclined portion 102. An inclination of the pressing portion 111 may be the same or different depending on the region. For example, the pressing portion 111 may have a straight structure inclined in the vertical direction. In addition, the pressing portion 111 may include two or more sections having different inclinations in the vertical direction according to regions. In addition, the pressing portion 111 may have a rounded structure in at least one section. In addition, the pressing portion 111 may include a horizontal section at an inner end where the pressing portion 111 meets the inner inclined portion 102.

A straight line from the inner end to the outer end of the pressing portion 111 may have an inclination angle (a) inclined upward at an angle with respect to a direction orthogonal to the vertical direction. Accordingly, the outer end of the pressing portion 111 may be disposed above the inner end of the pressing portion 111. A vertical height h1 of the outer end of the pressing portion 111 with respect to the inner end of the pressing portion 111 may be about 7 μm to about 10 μm.

The outer end of the pressing portion 111 is connected to a gas injection surface 112 of the wire discharge portion 110. The gas injection surface 112 may extend from the outer end of the pressing portion 111. A lower end portion of the gas injection surface 112 of the wire discharge portion 110 may be connected to the outer end of the pressing portion 111 and extend upward. A lower end portion of the gas injection surface 112 of the wire discharge portion 110 may have a predetermined inclination angle (B) with respect to a direction orthogonal to the vertical direction. The inclination angle (3) of the lower end portion of the gas injection surface 112 may be greater than the inclination angle (a) of the pressing portion 111. The inclination angle (a) of the lower end portion of the pressing portion 111 may be about 10 to about 25 degrees. The inclination of the gas injection surface 112 may be about 70 to about 85 degrees.

An injection hole 115 may be formed in an outer circumference of the wire discharge portion 110. A plurality of injection holes 115 may be formed around an outer circumference of the wire discharge portion 110. FIG. 4 illustrates a case in which six injection holes 115 are formed along a circumference direction of the wire discharge portion 110. When a plurality of injection holes 115 are provided, central angles between the injection holes 115 adjacent to each other may be the same. The plurality of injection holes 115 may be disposed at regular distances around the circumference direction of the wire discharge portion 110.

An outer end of the injection hole 115 may be disposed on the gas injection surface 112 of the wire discharge portion 110. The injection hole 115 may connect the gas injection surface 112 of the wire discharge portion 110 and the wire hole 101. The injection hole 115 may have a cross-section perpendicular to the length direction thereof, and may have a preset area. Accordingly, the injection hole 115 have a predetermined width W. For example, the width W of the injection hole 115 may be about 25 μm to about 30 μm. When the cross-section of the injection hole 115 is circular, the width W of the injection hole 115 may be a diameter of the injection hole 115. When the cross-section of the injection hole 115 is elliptical or polygonal, the width W of the injection hole 115 may be an arithmetic average value of distances between points facing each other based on the center in the cross-section of the injection hole 115.

The injection hole 115 may be spaced apart from the lower end of the wire discharge portion 110 upward by a predetermined distance (h). The height (h) from the lower end of the wire discharge portion 110 to the injection hole 115 may be about 80 μm to about 100 μm. The injection hole 115 may be spaced apart from the outer end portion of the pressing portion 111 upward by a predetermined distance h2. The height h2 from the outer end of the pressing portion 111 to the injection hole 115 may be greater than a vertical height h1 of the outer end of the pressing portion 111 with respect to the inner end of the pressing portion 111. The height h2 from the outer end of the pressing portion 111 to the injection hole 115 may be about 70 μm to about 93 μm.

An inlet flow passage 120 may be formed in a region along the length direction of the body 100 of the capillary 10. The inlet flow passage 120 may be formed in an upper region of the body 100 of the capillary 10. The inlet flow passage 120 may be connected to an external space through an outer surface of the body 100. The inlet flow passage 120 may have a cross section of a circular, elliptical, or polygonal shape perpendicular to a length direction thereof. The inlet flow passage 120 may pass through the body 100, and an inner end portion thereof may be connected to the wire hole 101.

An inlet-side fastening auxiliary portion 121 may be formed on the outer surface of the body 100. The inlet-side fastening auxiliary portion 121 may be formed in a region in which an outer end portion of the inlet flow passage 120 is disposed. The inlet-side fastening auxiliary portion 121 may have a groove structure. The groove structure may be recessed inward from the outer surface of the body 100. A cross-section of the inlet-side fastening auxiliary portion 121 along the length direction of the body 100 may have a semicircular shape or an arc shape. In addition, based on the cross section along the length direction of the body 100, the inlet-side fastening auxiliary portion 121 may have corners at one or more points. In addition, a cross-section of the inlet-side fastening auxiliary portion 121 along a direction crossing the length direction of the body 100 may have a semicircular shape or an arc shape. In addition, based on the cross section along a direction crossing the length direction of the body 100, the inlet-side fastening auxiliary portion 121 may have corners at one or more points.

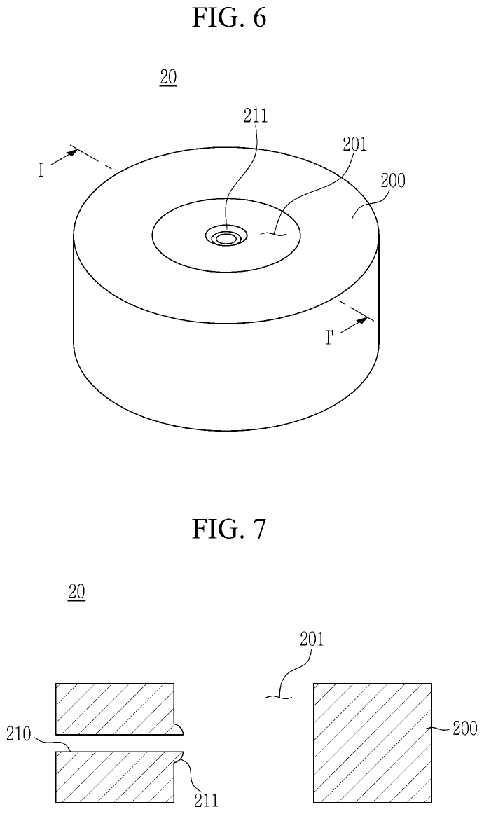

FIG. 6 illustrates a driving member of FIG. 1. FIG. 7 illustrates a longitudinal cross-sectional view taken along line I-I′ of FIG. 6.

Referring to FIG. 6 and FIG. 7, the driving member 20 may be coupled to the capillary 10. The driving member 20 may be detachably coupled to a portion of the outer surface of the capillary 10. The driving member 20 may include a driving body 200. A fastening space 201 to which the capillary 10 is coupled may be formed at one side of the driving body 200. The fastening space 201 may have a shape corresponding to at least a portion of an outer circumference of a partial section of the capillary 10. For example, as illustrated in FIG. 6, the fastening space 201 may be provided in a column shape corresponding to the outer circumference of the body 100 of the capillary 10 to be formed in an inner central region of the driving body 200. Accordingly, the capillary 10 may be coupled to the driving member 20 and a portion of the body 100 may be vertically inserted into the fastening space 201. In addition, the fastening space 201 may be provided to have a groove structure in which one side of the outer surface of the driving body 200 is recessed in a shape corresponding to a partial section of the outer circumference of the body 100 of the capillary 10. Accordingly, the capillary 10 may be coupled to the driving member 20 and one side of the outer surface of the body 100 may be fitted into the fastening space 201.

The driving member 20 may be movable in a three-dimensional space. Accordingly, a position of the capillary 10 coupled to the driving member 20 may be adjusted according to movement of the driving member 20. In addition, the driving member 20 may be provided to apply ultrasonic vibration to the capillary 10.

A supply passage 210 may be formed in the driving body 200. An end portion of the supply passage 210 may be connected to the fastening space 201.

A supply-side fastening auxiliary portion 211 may be formed on a surface facing the fastening space 201 in the driving body 200. The supply-side fastening auxiliary portion 211 may protrude toward the fastening space 201. The supply-side fastening auxiliary portion 211 may have a shape corresponding to the inlet-side fastening auxiliary portion 121. An end of the supply passage 210 may be disposed on the supply-side fastening auxiliary portion 211. Accordingly, when the capillary 10 is disposed in the fastening space 201 to be coupled to the driving member 20, the supply-side fastening auxiliary portion 211 may be disposed to engage with the inlet-side fastening auxiliary portion 121, and it may be determined whether or not the capillary 10 is correctly disposed with respect to the fastening space 201. Then, when the capillary 10 is properly disposed with respect to the fastening space 201, the supply passage 210 may be connected to the inlet flow passage 120.

A gas supply member 25 may be connected to the other end portion of the supply passage 210. The gas supply member 25 may supply gas through the injection hole 115. The gas supplied by the gas supply member 25 may be air, an inert gas such as nitrogen, etc. The gas supplied by the gas supply member 25 may be in a state in which contaminants such as dust are removed through filtering. The gas supply member 25 may be connected to the supply passage 210 through a supply pipe 26. The supply pipe 26 may be made of a flexible material, so that it may be easily bent. Accordingly, in response to a change in the position of the driving body 200, the position of the region connected to the driving body 200 of the supply pipe 26 may be changed.

The spool 31 may supply the wire 50 to the capillary 10. The spool 31 may be provided in a state in which the wire 50 is wound around an outer circumference thereof, and as the spool 31 rotates, the wound wire 50 may be released and supplied to the capillary 10. A direction of the wire 50 drawn out from the spool 31 may be controlled through a wire guide 32.

The clamp 33 is disposed in the section between the spool 31 and the capillary 10. Accordingly, the wire 50 supplied from the spool 31 to the capillary 10 may pass through the clamp 33. The clamp 33 may include a first gripping portion 33a and a second gripping portion 33b. A distance between the first gripping portion 33a and the second gripping portion 33b facing each other may be variable. The wire 50 may pass between the first gripping portion 33a and the second gripping portion 33b. Accordingly, when the distance between the first gripping portion 33a and the second gripping portion 33b is adjusted and the wire 50 is sandwiched between the first gripping portion 33a and the second gripping portion 33b, the wire 50 may be gripped by the clamp 33. In addition, the clamp 33 may be movable in a three-dimensional space. Accordingly, the position of the clamp 33 may be adjusted in response to the movement of the driving member 20. In addition, the height of the clamp 33 in the vertical direction with respect to the driving member 20 may be adjusted. Accordingly, the height of the clamp 33 with respect to the driving member 20 may be adjusted while holding the wire 50, thereby adjusting the tension applied to the wire 50 or adjusting the movement of the wire 50 with respect to the capillary 10.

A heating member 34 may be provided in a region adjacent to the lower end portion of the capillary 10. The heating member 34 may heat the wire 50 discharged from the capillary 10. For example, the heating member 34 may heat the wire 50 by generating an arc through discharge in a state adjacent to the wire 50. The wire 50 may form a ball through heating and melting through the heating member 34.

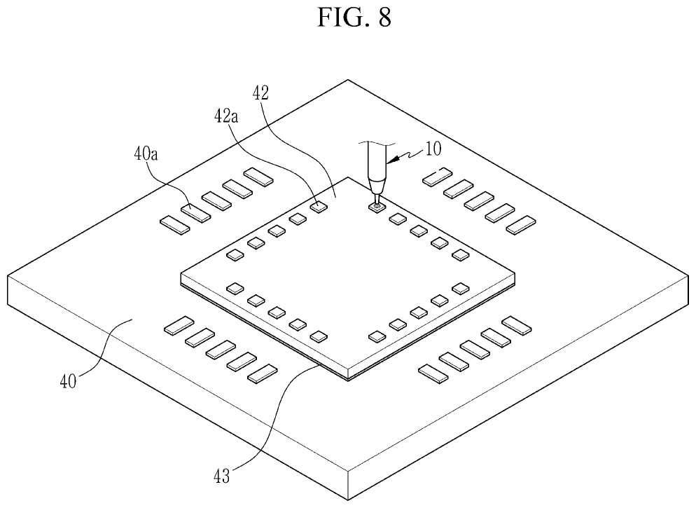

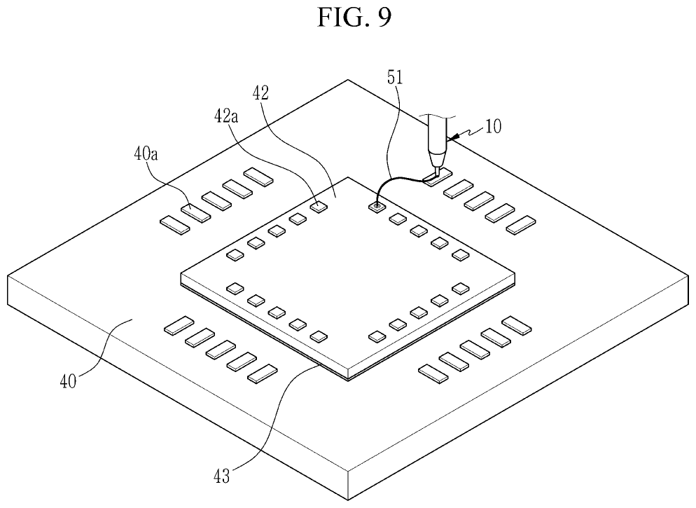

FIG. 8 illustrates a state in which primary bonding for manufacturing a semiconductor package is performed through the wire bonding apparatus of FIG. 1, and FIG. 9 illustrates a state in which secondary bonding for manufacturing a semiconductor package is performed through the wire bonding apparatus of FIG. 1.

Referring to FIG. 8 and FIG. 9, the wire bonding apparatus 1 according to an embodiment may enable an electronic element 42 to be connected to a substrate 40 by using a wire 50 for manufacturing a semiconductor package. The substrate 40 may be a ceramic substrate, a printed circuit board, lead frame, etc. The substrate 40 may include first and second surfaces facing each other. In FIG. 8 and FIG. 9, a case in which the first surface faces upward to become an upper surface and the second surface becomes a lower surface is illustrated. The substrate 40 may include at least one or more wire circuits. At least one or more substrate-side junction portions 40a may be disposed on the upper surface of the substrate 40. The substrate-side junction portion 40a may be provided with a conductive material. For example, the substrate-side junction portion 40a may be a connection pad connected to a wire circuit. In this case, the upper surface of the substrate-side junction portion 40a that is a connection pad may protrude outward from the upper surface of the substrate 40. In addition, the upper surface of the substrate-side junction portion 40a that is a connection pad may be coplanar with the upper surface of the substrate 40. In addition, the upper surface of the substrate-side junction portion 40a that is a connection pad may be recessed downward than the upper surface of the substrate 40 by a predetermined depth. In addition, the substrate-side junction portion 40a may be an end portion of a lead.

The electronic element 42 may be attached to the substrate 40. The electronic element 42 may be a semiconductor chip, an electronic device, or the like. The semiconductor chip may be a logic semiconductor chip, a memory semiconductor chip, or the like. At least one or more device-side junction portions 42a may be provided on an outer surface of the electronic element 42. The device-side junction portion 42a may be disposed on the upper surface of the electronic element 42. Due to a thickness of the electronic element 42, the device-side junction portion 42a may be disposed above the substrate-side junction portion 40a.

Prior to connection using the wire 50, the electronic element 42 may be attached to the upper surface of the substrate 40 through an adhesive layer 43. Accordingly, the semiconductor package may include the adhesive layer 43 disposed between the lower surface of the electronic element 42 and the upper surface of the substrate 40.

The wire bonding apparatus 1 may perform primary bonding of the wire 50. The primary bonding may be performed on the device-side junction portion 42a of the electronic element 42. The primary bonding may be performed by forming a ball at the end portion of the wire 50 discharged to the lower end of the capillary 10 through the heating member 34 and attaching the ball to the device-side junction portion 42a.

Thereafter, the wire bonding apparatus 1 may perform secondary bonding of the wire 50. To this end, the capillary 10 may be moved to an upper position of an attachment target region in which the secondary bonding may be performed while discharging and supplying the wire 50 downward. The attachment target region in which the secondary bonding is performed may be the substrate-side junction portion 40a of the substrate 40.

In addition, the primary bonding may be performed on the substrate-side junction portion 40a, and the secondary bonding may be performed on the device-side junction portion 42a.

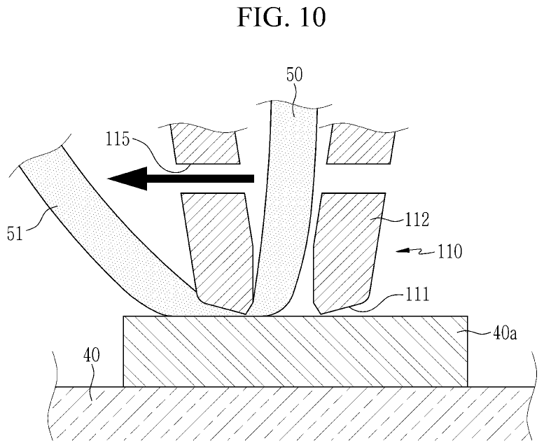

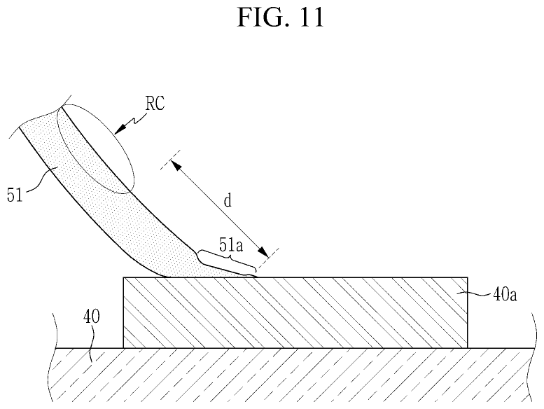

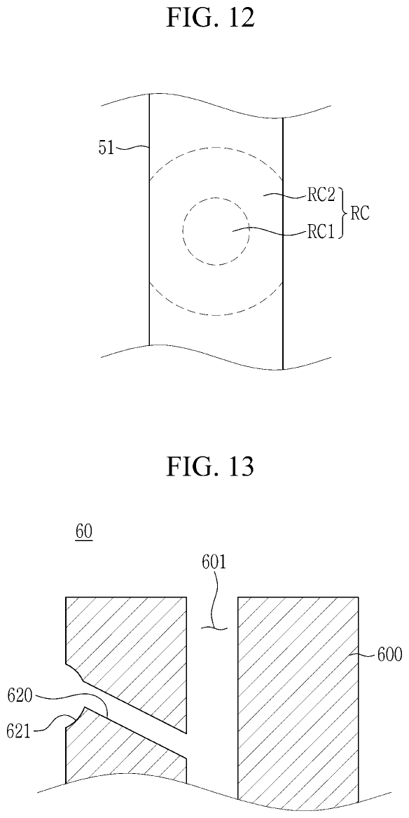

FIG. 10 illustrates a state when secondary bonding of a wire is performed at a lower end portion of a capillary. FIG. 11 illustrates an end portion of a connection wire of a semiconductor package after a wire is attached. FIG. 12 illustrates a roughness change region viewed from a direction crossing a longitudinal direction of a connection wire.

Referring to FIG. 10, FIG. 11, and FIG. 12, the capillary 10 may move downward to be disposed in an upper space of the attachment target region, so that the wire 50 may be attached while being pressed with respect to the attachment target region. In this case, the wire bonding apparatus 1 may enable ultrasonic vibration to be applied to the capillary 10 and the wire 50 may be melted and attached. When the capillary 10 rises, the wire 50 may be cut. The wire 50 in which the primary bonding and the secondary bonding have been performed at both ends after being discharged from the capillary 10 may become a wire 51 that is bonded to the substrate-side junction portion 40a and the device-side junction portion 42a in the semiconductor package. In addition, the connection wire 51 may be pressed while in contact with the lower end portion of the capillary 10 during the secondary bonding process, so that it may include a stitch bond area 51a having a shape corresponding to the lower end portion of the capillary 10.

The pressurization of the wire 50 by the capillary 10 may be performed by the pressing portion 111 at the lower end portion of the capillary 10. In addition, the wire bonding apparatus 1 may move the capillary 10 downward to supply gas to the capillary 10 through the gas supply member 25 while the secondary bonding is performed, so that the gas may be supplied through the injection hole 115. When the secondary bonding is performed, the injection hole 115 may be provided to face the direction in which the wire 50 is disposed in the outer space of the capillary 10. Specifically, when the secondary bonding is performed, the wire 50 supplied to the outside of the capillary 10 may be disposed in a region in which the substrate-side junction portion 40a and the device-side junction portion 42a face each other. Accordingly, at least one of the gas injection holes 115 may be directed to a direction in which the substrate-side junction portion 40a and the device-side junction portion 42a face each other, spraying gas toward the wire 50 supplied to the outside of the capillary 10. When a plurality of gas injection holes 115 are provided around the outer circumference of the capillary 10, in a state in which additional control may be omitted for the direction of the gas injection holes 115, at least one of the gas injection holes 115 may face a direction in which the substrate-side junction portion 40a and the device-side junction portion 42a face each other.

When the secondary bonding is performed, a region of the wire 50 adjacent to the attachment target region may be melted. Accordingly, since the outer surface of the wire 50 has viscosity, a phenomenon in which the wire 50 is attached to the upper region of the pressing portion 111 at the lower end portion of the wire discharge portion 110 may occur. In addition, while the wire 50 bonding process is performed, the substrate 40 may be heated to improve adhesion of the wire 50. In this case, fumes may be generated in the adhesive layer 43 and the like, and when the fumes adhere to the outer surface of the wire 50 or the wire discharge portion 110, the wire 50 may be attached to the upper region of the pressing portion 111. As described above, when the capillary 10 rises to complete the cutting of the wire 50 and the secondary bonding process in the state in which the wire 50 is attached to the upper region of the pressing portion 111, the force generated when the wire 50 is separated from the outer surface of the wire discharge portion 110 may act on the wire 50 attached to the attachment target region. This force may cause a crack in the region in which the secondary bonding is performed in the connection wire 51. Particularly, the crack may be concentrated in the stitch bond region 51a.

On the other hand, in the wire bonding apparatus 1 according to an embodiment, when the secondary bonding is performed, gas may be supplied toward the wire 50, and a gas layer may be formed between the wire 50 discharged from the capillary 10 and the wire discharge portion 110. Accordingly, in the process of the secondary bonding, the wire 50 may be prevented from being attached to the gas injection surface 112 of the wire discharge portion 110, or a region in which the wire 50 is attached to the gas injection surface 112 of the wire discharge portion 110 may be reduced or minimized. In addition, the gas may prevent fumes from adhering to a region in which the wire 50 and the gas injection surface 112 of the wire discharge portion 110 face each other. Accordingly, when the capillary 10 rises to complete the cutting of the wire 50 and the secondary bonding process, a force generated in the process of separating the wire 50 from the outer surface of the wire discharge portion 110 may be reduced or minimized, thereby substantially preventing cracks from being generated in the region in which the secondary bonding is performed.

The connection wire 51 included in the semiconductor package may have a roughness change region RC. The roughness change region RC may be a region onto which a gas is supplied from the injection hole 115 during the secondary bonding process. The roughness change region RC may be disposed apart from the stitch bond region 51a and formed between end portions of the connection wire 51. In addition, based on the cross-section crossing the length direction of the connection wire 51, the roughness change region RC may be disposed in a region opposite to the direction in which the substrate-side junction portion 40a and the device-side junction portion 42a face each other.

As the roughness change region RC may be formed in the region onto which the gas is supplied from the injection hole 115, the roughness change region RC may be spaced apart from an end of the connection wire 51 by a predetermined distance (d). For example, the distance d between the roughness change region RC and an end of the connection wire 51 may be about 28 μm to about 31 μm.

The roughness change region RC may be provided with lower roughness than an adjacent region. The roughness change region RC may be smoother than the adjacent region. The roughness change region RC and the adjacent region may be disposed along a surface of the connection wire 51. The adjacent region may surround the roughness change region RC. The roughness change region RC may have a lower roughness than a region disposed in an opposite direction based on a cross-section crossing a length direction of the connection wire 51.

The stitch bond region 51a may be outside of the roughness change region RC. Specifically, the roughness change region RC may be formed while the surface thereof is smoothed due to the gas supplied onto the wire 50 in a heated state during the bonding process, and the roughness may be lowered. In addition, by reducing fumes in an area of the roughness change region RC, the roughness change region RC may have lower roughness than the adjacent region. For example, the roughness of the roughness change region RC may have a measured value of about 1 μm to about 3 μm according to ten point height of irregularities (Rz).

In addition, the density or speed of gas injected during the bonding process may be greater in a region in which the central axis of the length direction of the injection hole 115 is disposed than in an outer region thereof. Accordingly, in the roughness change region RC, a central region RC1 may have lower roughness than an outer region RC2. That is, the connection wire 51 included in the semiconductor package may have a region whose roughness increases from the central region RC1 to the outer region RC2 in the direction in which the stitch bond region 51a is formed.

FIG. 13 illustrates a longitudinal cross-sectional view along a length direction of a partial section of a capillary according to an embodiment.

Referring to FIG. 13, a body 600 of a capillary 60 may have a predetermined length. A cross-section according to a direction crossing a length direction of the body 600 may have a circular, elliptical, or polygonal shape. A wire hole 601 may be formed in an inner central area of the body 600 along the length direction. The wire hole 601 may be formed through the body 600 from an upper end to a lower end of the body 600. The wire hole 601 may be an opening for the wire 50. The wire 50 may move through the wire hole 601, which may be a path for the wire 50 to travel along.

An inlet flow passage 620 may be formed in a region along the length direction of the body 600. The inlet flow passage 620 may be formed in an upper region of the body 600. The inlet flow passage 620 may be exposed to an external space through an outer surface of the body 600. The inlet flow passage 620 may have a circular, elliptical, or polygonal shape of a cross section perpendicular to a length direction thereof. The inlet flow passage 620 may pass through the body 600, and an inner end portion thereof may be connected to the wire hole 601. An inner end portion of the inlet flow passage 620 disposed in an inner central region of the body 600 may be inclined downward. In addition, the inlet flow passage 620 may be inclined downward from the outer end portion to the inner end portion. Accordingly, gas supplied through the inlet flow passage 620 may form a down flow to be effectively supplied toward a lower end portion of the capillary 60.

An inlet-side fastening auxiliary portion 621 may be formed on an outer surface of the body 600. The inlet-side fastening auxiliary portion 621 may be formed in a region in which an outer end portion of the inlet flow passage 620 is disposed. A cross-section of the inlet-side fastening auxiliary portion 621 along the length direction of the body 600 may have a semicircular shape or an arc shape. In addition, the inlet-side fastening auxiliary portion 621 may have corners at one or more points in a cross-section along a direction crossing the length direction of the body 600. The inlet flow passage 620 may be inclined downward from the inlet-side fastening auxiliary portion 621 to the inner end portion.

The remaining parts of the capillary 60 that are not described may be the same as or similar to those of the capillary 10 described above with reference to FIG. 3 to FIG. 5. Accordingly, repeated descriptions are omitted.

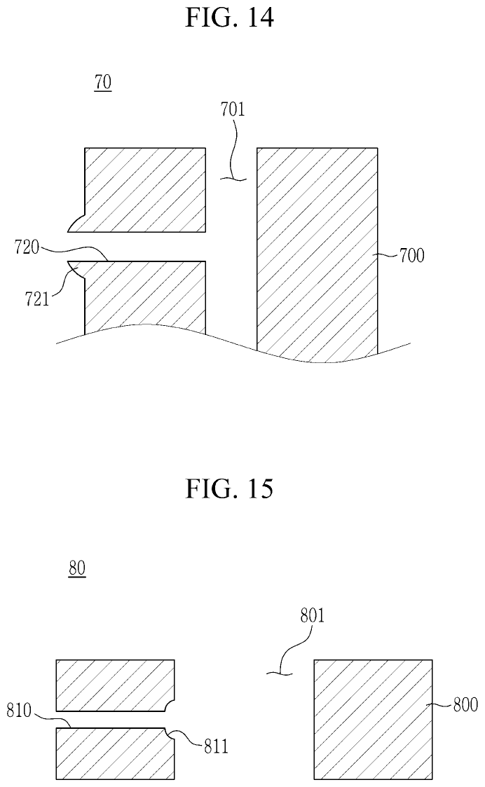

FIG. 14 illustrates a longitudinal cross-sectional view along a length direction of a partial section of a capillary according to an embodiment.

Referring to FIG. 14, a body 700 of a capillary 70 may have a predetermined length. A cross-section according to a direction crossing a length direction of the body 700 may have a circular, elliptical, or polygonal shape. A wire hole 701 may be formed in an inner central area of the body 700 along the length direction. The wire hole 701 may be formed through the body 700 from an upper end to a lower end of the body 700. The wire hole 701 may be an opening for the wire 50. The wire 50 may move through the wire hole 701, which may be a path for the wire 50 to travel along.

An inlet flow passage 720 may be formed in one region along the length direction of the body 700. The inlet flow passage 720 may be formed in an upper region of the body 700. The inlet flow passage 720 may be exposed to an external space through an outer surface of the body 700. The inlet flow passage 720 may pass through the body 700, and an inner end portion thereof may be connected to the wire hole 701.

An inlet-side fastening auxiliary portion 721 may be formed on the outer surface of the body 700. The inlet-side fastening auxiliary portion 721 may be formed in a region in which an outer end portion of the inlet flow passage 720 is disposed.

The inlet-side fastening auxiliary portion 721 may be provided to have a protrusion structure protruding in an outer direction from an outer surface of the body 700. A cross-section of the inlet-side fastening auxiliary portion 721 along the length direction of the body 700 may have a semicircular shape or an arc shape. In addition, the inlet-side fastening auxiliary portion 721 may have corners at one or more points in a cross-section along the length direction of the body 700. In addition, a cross-section of the inlet-side fastening auxiliary portion 721 along a direction crossing the length direction of the body 700 may have a semicircular shape or an arc shape. In addition, the inlet-side fastening auxiliary portion 721 may have corners at one or more points in a cross-section along a direction crossing the length direction of the body 700.

The remaining parts of the capillary 70 that are not described may be the same as or similar to those of the capillary 10 described above with reference to FIG. 3 to FIG. 5. Alternatively, the remaining parts of the capillary 70 that are not described may be the same as or similar to those of the capillary 60 described above with reference to FIG. 13. Accordingly, repeated descriptions are omitted.

FIG. 15 illustrates a longitudinal cross-sectional view of a driving member according to an embodiment.

Referring to FIG. 15, a driving member 80 is coupled to the capillary 10, capillary 60, or capillary 70. The driving member 80 may be detachably coupled to a portion of an outer surface of the capillary 10, capillary 60, or capillary 70. The driving member 80 includes a driving body 800. A fastening space 801 to which the capillary 10, capillary 60, or capillary 70 is coupled may be formed at one side of the driving body 800.

A supply passage 810 may be formed in the driving body 800. An end portion of the supply passage 810 may be connected to the fastening space 801.

A supply-side fastening auxiliary portion 811 may be formed on a surface facing the fastening space 801 in the driving body 800. The supply-side fastening auxiliary portion 811 may have a groove structure that is recessed in an opposite direction of the fastening space 801. The supply-side fastening auxiliary portion 811 may have a shape corresponding to the inlet-side fastening auxiliary portion 721 of the capillary 70 according to an embodiment of FIG. 14. A cross-section of the supply-side fastening auxiliary portion 811 along the length direction of the driving body 800 may have a semicircular shape or an arc shape. In addition, the supply-side fastening auxiliary portion 811 may have corners at one or more points in a cross-section along a direction crossing the length direction of the driving body 800.

An end of the supply passage 810 may be disposed on the supply-side fastening auxiliary portion 811. Accordingly, when the capillary 70 is disposed in the fastening space 801, the supply-side fastening auxiliary portion 811 may be disposed at the inlet-side fastening auxiliary portion 721, and it may be determined whether or not the capillary 70 is correctly disposed with respect to the fastening space 801. Then, when the capillary 70 is properly disposed with respect to the fastening space 801, the supply passage 810 may be connected to the inlet flow passage 720.

Certain parts of the driving member 80 may be the same as or similar to those of the driving member 20 described above with reference to FIG. 6 and FIG. 7. Accordingly, repeated descriptions may be omitted.

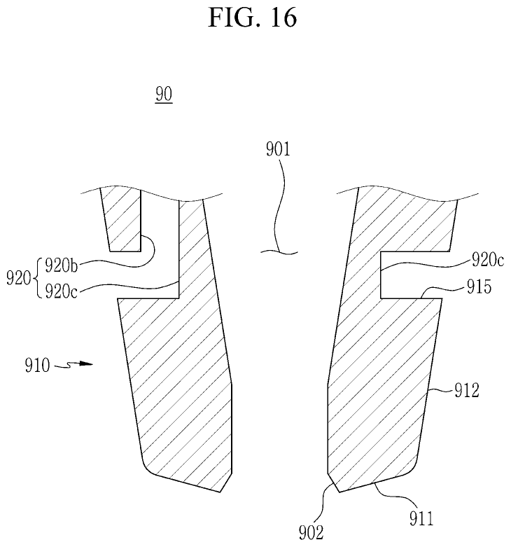

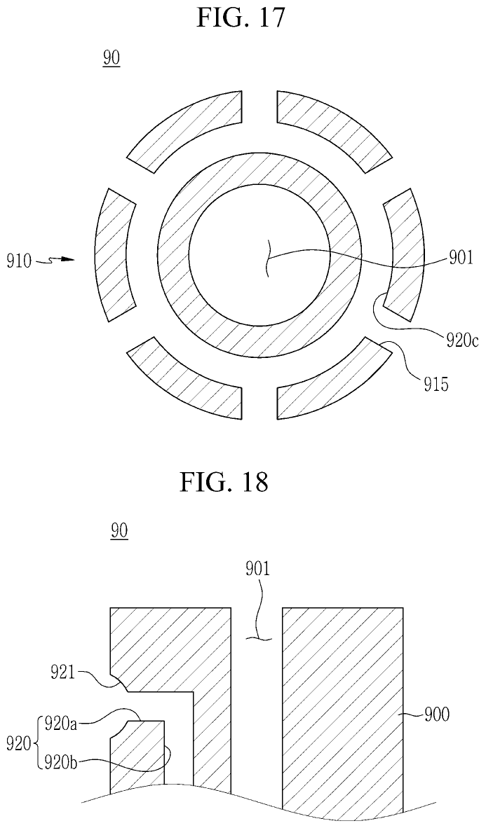

FIG. 16 illustrates a longitudinal cross-sectional view along a length direction of a lower end portion of a capillary according to an embodiment, FIG. 17 illustrates a transverse cross-sectional view along a direction crossing a length direction of a lower end portion of a capillary according to an embodiment, and FIG. 18 illustrates a longitudinal cross-sectional view along a length direction of a partial section of a capillary according to an embodiment.

Referring to FIG. 16 and FIG. 18, a body 900 of a capillary 90 may have a predetermined length. A cross-section according to a direction crossing a length direction of the body 900 may have a circular, elliptical, or polygonal shape. A wire hole 901 may be formed in an inner central area of the body 900 along the length direction. The wire hole 901 may be formed through the body 900 from an upper end to a lower end of the body 900. The wire hole 901 may be an opening for the wire 50. The wire 50 may move through the wire hole 901, which may be a path for the wire 50 to travel along.

A wire discharge portion 910 may be disposed at a lower end portion of the body 900. The wire discharge portion 910 discharges the wire 50 downward. An area of a cross-section of a direction crossing a length direction of the wire discharge portion 910 may be smaller than the area of the cross-section of the direction crossing the length direction of the upper portion of the body 900.

An inner inclined portion 902 may be formed in an inner central region of a lower end portion of the wire discharge portion 910. The inner inclined portion 902 may be inclined toward the outside as it goes downward. Accordingly, the area of the cross-section of the lower end portion of the wire hole 901 crossing the length direction thereof may increase downward.

An inclination value of the inner inclined portion 902 may be the same or different depending on regions. For example, the inner inclined portion 902 may have a straight structure inclined in a vertical direction. In addition, the inner inclined portion 902 may include two or more sections having different inclinations in the vertical direction according to regions. In addition, the inner inclined portion 902 may include a portion that is rounded toward an outer direction as it goes downward in at least some sections.

A pressing portion 911 may be formed in an outer region of a lower end portion of the wire discharge portion 910. The pressing portion 911 may be connected to a lower end of the inner inclined portion 902. The pressing portion 911 may extend from the lower end of the inner inclined portion 902. The pressing portion 911 may meet the lower end of the inner inclined portion 902 at an angled portion. The angled portion may be a vertex or may be rounded. At least one area of the pressing portion 911 may be inclined upward toward the outside.

A lower end of a gas injection surface 912 of the wire discharge portion 910 may be connected to the outer end portion of the pressing portion 911 to extend upward. The lower end of a gas injection surface 912 of the wire discharge portion 910 may extend upward from the outer end portion of the pressing portion 911. The lower end of the gas injection surface 912 of the wire discharge portion 910 may have a predetermined inclination angle with respect to a direction orthogonal to the vertical direction. The inclination of the lower end portion of the gas injection surface 912 may have a greater value than the inclination angle of the pressing portion 911. The inclination of the lower end portion of the gas injection surface 912 may be closer to the vertical than the inclination of the pressing portion 911. The inclination of the lower end portion of the gas injection surface 912 may be between about 70 to about 85 degrees. The inclination of the pressing portion 911 may be between about 10 to about 25 degrees.

One or more injection holes 915 may be formed in the wire discharge portion 910. FIG. 17 illustrates a case in which six injection holes 915 may be formed along a circumference direction of the wire discharge portion 910. When a plurality of injection holes 915 are provided, central angles between the injection holes 915 adjacent to each other may be the same. The plurality of injection holes 915 may be disposed at regular distances around the circumference direction of the wire discharge portion 910.

An outer end of the injection hole 915 may be formed at an outer circumference of the gas injection surface 912. The injection hole 915 may have a cross-section perpendicular to the length direction thereof having a predetermined area. Accordingly, the injection hole 915 may have a predetermined width. An inner end of the injection hole 915 may be partitioned from the wire hole 901 disposed inside the body 900. The injection hole 915 may be spaced apart from the lower end of the wire discharge portion 910. The injection hole 915 may be spaced above the lower end of the wire discharge portion 910 by a predetermined distance.

The injection hole 915 may be spaced apart from the outer end portion of the pressing portion 911. The injection hole 915 may be spaced above the outer end portion of the pressing portion 911 by a predetermined distance.

An inlet flow passage 920 may be formed in a region along the length direction of the body 900 of the capillary 90. The inlet flow passage 920 may supply the gas supplied from the outside of the capillary 90 to the injection hole 915. An end of the inlet flow passage 920 may be disposed on the outer surface of the body 900. The other end of the inlet flow passage 920 may be connected to the inner end portion of the injection hole 915.

The inlet flow passage 920 may include an inlet portion 920a, a connection portion 920b, and a distribution portion 920c.

An outer end of the inlet portion 920a may be exposed to an external space through an outer surface of the body 900. The inlet portion 920a may be formed in an upper region of the body 900. An inner end portion of the inlet portion 920a may be separated from the wire hole 901 and formed inside the body 900.

An end portion of the connection portion 920b may be connected to the inner end portion of the inlet portion 920a. The connection portion 920b may extend toward an area in which the injection hole 915 is formed from an area in which the outer end portion of the inlet portion 920a is formed, inside the body 900.

The distribution portion 920c may be connected to the other end portion of the connection portion 920b. The distribution portion 920c may be separated from the wire hole 901 and formed inside the body 900. The distribution portion 920c may be formed in a ring shape and may be connected to inner ends of a plurality of injection holes 915. Accordingly, after being distributed through the distribution portion 920c, the gas may be injected into the external space of the capillary 90 through the plurality of injection holes 915. In addition, when one injection hole 915 is formed in the capillary 90, the distribution portion 920c may be omitted, and the other end portion of the connection portion 920b may be directly connected to the inner end portion of the injection hole 915.

An inlet-side fastening auxiliary portion 921 may be formed on the outer surface of the body 900. The inlet-side fastening auxiliary portion 921 may be formed in a region in which an outer end portion of the inlet portion 920a is disposed. A cross-section of the inlet-side fastening auxiliary portion 921 along the length direction of the body 900 may have a semicircular shape or an arc shape. In addition, the inlet-side fastening auxiliary portion 921 may have corners at one or more points in a cross-section along a direction crossing the length direction of the body 900.

The capillary 90 according to an embodiment may be configured such that the path through which the gas flows may be partitioned from the path through which the wire moves. Accordingly, the gas may be stably injected through the injection hole 915. The gas may be stably injected through the injection hole 915 without being affected by the moving state of the wire 50 or the extent to which the lower end of the wire hole 901 may be blocked by the wire 50 during the bonding process. In addition, by adjusting the amount of gas supplied from the gas supply member 25, supply pressure, and the like, it may be possible to stably adjust the amount and pressure of gas injected through the injection hole 915.

Other parts of the capillary 90 may be the same as or similar to those of the capillary 10 described above with reference to FIG. 3 to FIG. 5. Alternatively, other parts of the capillary 90 may be the same as or similar to those of the capillary 60 described above with reference to FIG. 13. Alternatively, other parts of the capillary 90 may be the same as or similar to those of the capillary 70 described above with reference to FIG. 14. Accordingly, repeated descriptions may be omitted.

While embodiments of the present disclosure has been described in connection with what is presently considered to be practical embodiments, it is to be understood that the disclosure is not limited to the disclosed aspects, but, on the contrary, is intended to cover various modifications and equivalent arrangements included within the spirit and scope of the appended claims.

### DESCRIPTION OF SYMBOLS

10: capillary
20: driving member
31: spool
32: wire guide
33: clamp
34: heating member
100: body
101: wire hole
102: inner inclined portion
110: wire discharge portion
111: pressing portion
112: gas injection surface
115: injection hole
120: inlet flow passage
121: inlet-side fastening auxiliary portion
200: driving body
201: fastening space
210: supply passage
211: supply-side fastening auxiliary portion

What is claimed is:

1. A capillary of a wire bonding apparatus, the capillary comprising:
a body having a wire hole formed in an inner central region of the body and through a length of the body; and
a wire discharge portion disposed at a lower end portion of the body and comprising an injection hole in an outer circumference of the wire discharge portion.

2. The capillary of claim 1, wherein the wire discharge portion comprises:
a pressing portion disposed at a lower end portion of the wire discharge portion and inclined upward toward an outward direction of the wire discharge portion in at least one region; and
a gas injection surface extending upward from the pressing portion,
wherein an outer end of the injection hole is disposed on the gas injection surface.

3. The capillary of claim 2, wherein an inclination of a lower end portion of the gas injection surface is greater than an inclination of the pressing portion with respect to a direction orthogonal to a vertical direction.

4. The capillary of claim 2, wherein a height from an outer end portion of the pressing portion to the injection hole is greater than a height of an inner end of the pressing portion.

5. The capillary of claim 1, wherein an inner end portion of the injection hole is connected to the wire hole.

6. The capillary of claim 5, further comprising an inlet flow passage that passes through the body and connects the wire hole to an outer surface of the body.

7. The capillary of claim 6, wherein the inlet flow passage is inclined downward to the inner end portion.

8. The capillary of claim 6, wherein an inlet-side fastening auxiliary portion is formed in an area in which an outer end portion of the inlet flow passage is disposed on an outer surface of the body, and the inlet-side fastening auxiliary portion comprises a groove structure inwardly recessed or a protrusion structure outwardly protruding.

9. The capillary of claim 8, wherein the wire bonding apparatus comprises:
a spool supplying a wire to the capillary;
a driving member movable in a three-dimensional space and including a driving body having a fastening space in which the capillary is coupled; and
a supply passage connected to the fastening space and formed in the driving body.

10. The capillary of claim 9, wherein a supply-side fastening auxiliary portion formed on a surface facing the fastening space has a protrusion structure or a groove structure corresponding to the inlet-side fastening auxiliary portion formed in the driving body.

11. The capillary of claim 1, wherein the body includes an inlet flow passage having a first end disposed on an outer surface of the body and a second end connected to an inner end portion of the injection hole.

12. The capillary of claim 11, wherein the inlet flow passage comprises:
an inlet portion including an outer end exposed to an external space through an outer surface of the body;
a connection portion connected to an inner end portion of the inlet portion; and
a distribution portion connected to the connection portion and an inner end portion of the injection hole.

13. The capillary of claim 12, wherein the distribution portion is formed in a ring shape.

14. A wire bonding apparatus comprising:
a capillary for discharging a wire;
a spool for supplying the wire to the capillary; and
a driving member coupled to the capillary and movable in a three-dimensional space,
wherein the capillary comprises:
a body having a wire hole formed in an inner central region of the body and through a length of the body, and through which the wire is discharged; and
a wire discharge portion disposed at a lower portion of the body,
wherein the wire discharge portion comprises:
a pressing portion disposed at a lower end portion of the wire discharge portion and inclined upward toward an outward direction the wire discharge portion in at least one region; and
a gas injection surface extending upward from the pressing portion and having an outer circumference at which an outer end of an injection hole for spraying gas is disposed.

15. The wire bonding apparatus of claim 14, wherein a height from an outer end portion of the pressing portion to the injection hole is greater than a height of an inner end of the pressing portion.

16. A semiconductor package comprising:
a substrate having a substrate-side junction portion;
an electronic device attached to the substrate and having a device-side junction portion; and
a connection wire having a first end portion bonded to the substrate-side junction portion and a second end portion bonded to the device-side junction portion,
wherein the connection wire has a roughness change region having lower roughness than a region adjacent to at least one of the first end portion and the second end portion.

17. The semiconductor package of claim 16, wherein the roughness change region is disposed adjacent to a stitch bond region of the connection wire.

18. The semiconductor package of claim 17, wherein the roughness change region has a lower roughness than a region disposed in an opposite direction based on a cross-section crossing a length direction of the connection wire.

19. The semiconductor package of claim 17, wherein a roughness of a central region of the roughness change region is lower than that of an outer region thereof.

20. The semiconductor package of claim 17, wherein the roughness change region is spaced apart from an end of the connection wire by about 28 μm to about 31 μm.
